(19) United States
(12) Patent Application Publication
(10) Pub. No.: US 2025/0235978 A1
(43) Pub. Date: Jul. 24, 2025

(54) COOLING CONTROL IN CHEMICAL MECHANICAL POLISHING

(71) Applicant: Lapmaster International, LLC, Mt Prospect, IL (US)

(72) Inventors: Robert Lewis Rhoades, Fishers, IN (US); Czeslaw Gibas, Norwood Park, IL (US); Isaak Garbar, Vernon Hills, IL (US)

(21) Appl. No.: 19/032,936

(22) Filed: Jan. 21, 2025

Related U.S. Application Data
(60) Provisional application No. 63/624,545, filed on Jan. 24, 2024.

(51) Int. Cl. B24B 37/015; H01L 21/306; H10D 62/832

(52) U.S. Cl. CPC B24B 37/015; H01L 21/30625; H10D 62/8325

(57) ABSTRACT

A wafer polishing apparatus for abrasively polishing silicon carbide semiconductor materials is adapted to maintains an advantageous temperature at a wafer/polishing surface interface and includes a rotating circular platen having a polishing pad with a circular aluminum backing plate with an increased diameter compared to standard platens. It also includes one or more overhead oscillating carriers for moving the wafer over the rotating platen such that the increased diameter results in an enlarged wafer track. The apparatus also includes a slurry delivery circuit to distribute chilled slurry to the wafer/polishing surface interface via delivery tubes suspended over the platen.

### CROSS-REFERENCE TO RELATED APPLICATIONS

Pursuant to 35 USC 119 (e), this application claims priority to U.S. Provisional Patent Application No. 63/624,545 filed Jan. 24, 2024, the disclosure of which is incorporated herein by reference in its entirety and for all purposes.

### BACKGROUND

Single-crystal silicon carbide (SiC) is gaining popularity as a wide bandgap semiconductor for the fabrication of hybrid power devices. Growing demand exists for numerous applications, such as inverter modules, charging circuitry for electric vehicles, voltage regulators for converting stored energy to alternating current, and uninterruptible power supplies for large data centers and network infrastructure. Demand for SiC wafers to build such power devices exceeds current production capacity.

As a material, SiC has very low chemical reactivity and has a hardness value second only to diamond among naturally occurring materials. Accordingly, it is very slow and expensive to slice, grind, and polish SiC wafers compared to other semiconductor wafers.

During wafer polishing, the wafer is held in a rotating carrier and the carrier presses the face of the wafer against a polishing surface of a rotating polishing pad while chemical mechanical polishing (CMP) slurry is dispensed adjacent the wafer/polishing surface interface to maintain both lubrication and delivery of chemicals and abrasives to the polishing surface. The sliding friction due to the relative rotation between the wafer and the polishing surface accomplishes removal of wafer surface material but also generates heat in the annular region of the pad often referred to as the “wafer track”. The track that extends annularly around the polishing pad is defined by the diameter of the wafer plus a small sweeping motion of the wafer imparted by oscillation of the polishing head and wafer carrier. Such motion averages out some of the inherent process anomalies and gives a more uniform removal profile across the wafer.

The pad material is usually a polymeric material, and therefore, functions as a thermal insulator. The surface temperature generally rises within the wafer track as polishing proceeds until an approximate balance is achieved between the average amount of energy per unit area being generated at the surface and the energy per unit area being dissipated through various cooling mechanisms of the machine.

The SiC wafer chemical mechanical polishing process requires long polish times of several minutes or more, slurries with specialized chemical ingredients, and more aggressive pressures and speeds than are needed for most other materials. Aggressive process conditions result in a buildup of heat in the polishing pad surface which creates problems from two perspectives.

First, most polishing pads are made from polyurethane or similar polymers which can undergo inelastic deformation at elevated temperatures. This causes a smoothing of the surface texture which causes diminished effectiveness and lowered polishing removal rate. It has been recognized that this effect becomes significant when the pad surface temperature approaches 60 degrees C. or above. Second, the chemistries used in most SiC slurries are based on permanganate oxidizers. Such slurries have been observed to become unstable or degrade when exposed to excess temperature during the polishing process. It is generally recognized as necessary to keep the pad surface temperature below 55 degrees C. to maintain slurry effectiveness.

Maintaining low pad surface temperature becomes difficult under aggressive process conditions intended to increase productivity but necessarily generates more heat. Therefore, to avoid the deleterious effects described above, operational process temperatures must be effectively maintained to assure adequate heat dissipation from the pad surface.

### SUMMARY

The present invention incorporates multiple adaptations to improve the cooling effectiveness of a wafer polisher to provide adequate cooling of the pad surface temperature during aggressive polishing processes such as silicon carbide wafer polishing. These adaptations function collectively to achieve superior cooling performance and result in higher productivity. Specifically, this cumulative result derives from the use of the disclosed combination of features in a unified application. As disclosed herein, the goal is achieved through integration of the following:
1. A large platen diameter to increase active surface area in wafer track. (lower percentage of pad coverage by wafer)
2. Platen cooling. (achieves heat dissipation from undersurface of pad)
3. An aluminum platen. (improved heat transfer compared to stainless steel or ceramic)
4. A flow-through heat exchanger to chill slurry dispensed onto polishing pad. (controls pad surface temperature)

### DESCRIPTION OF THE DRAWINGS

FIG. 1 is a perspective view of a wafer polishing machine incorporating the principles of the disclosure illustrating the exterior enclosure and other features of the machine.

FIG. 2 is a perspective view of the base frame of the wafer polishing machine of FIG. 1.

FIG. 3 is a top plan view of the operating elements of the wafer polishing machine of FIG. 1.

FIG. 4 is a perspective view of a platen assembly of the wafer polishing machine of FIG. 1.

FIG. 5 is an enlarged sectional view of the platen assembly of FIG. 4.

FIGS. 6 and 7 are perspective views of a polishing head assembly of the wafer polishing machine of FIG. 1.

FIGS. 8 and 9 are perspective views of pad conditioner components of the wafer polishing machine of FIG. 1.

FIG. 10 is a schematic view of a flow-through heat exchanger for slurry cooling.

### DETAILED DESCRIPTION

Implementation of a semiconductor wafer polishing machine embodying the principles of the present disclosure may include conventional features of present commercial devices. The combination contemplated herein provides the benefits disclosed and may be achieved without regard to the number of polishing stations included in the device. The structures described herein and illustrated in the accompanying drawings are merely exemplary, and not limiting.

The accompanying drawings illustrate a wafer polisher generally designated 100, which includes multiple (two) platens and multiple (four) individual polishing head assemblies. It is, therefore, capable of polishing from one to four wafers (sometimes referred to as substrates) at the same time. Any number of stations, however, may be employed.

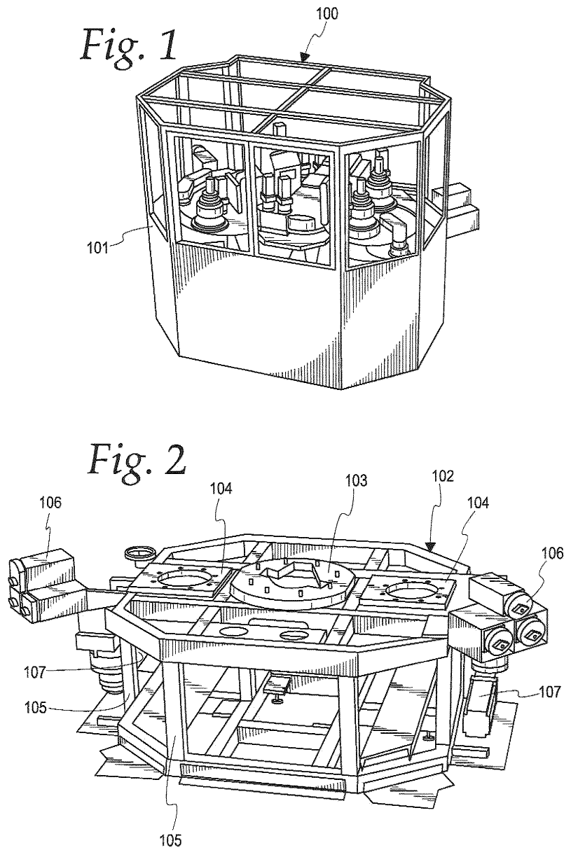

Referring to FIG. 1, the wafer polishing machine 100 includes exterior panels 101 providing visual access to the machine interior. A structural base frame 102 shown in FIG. 2 supports the operating elements of the machine. As shown, the machine frame 102 is transversely elongated with a central pedestal 103, bounded laterally by two polishing assembly mounts 104. This structure is supported by vertical beams 105. Notably, the frame 102 supports two groupings of fluid pumps 106 adjacent the perimeter edge of the frame 102. These pumps supply water and slurry to the operating fluid paths. Polishing assembly drive motors 107 are also supported on frame 102 near mounts 104.

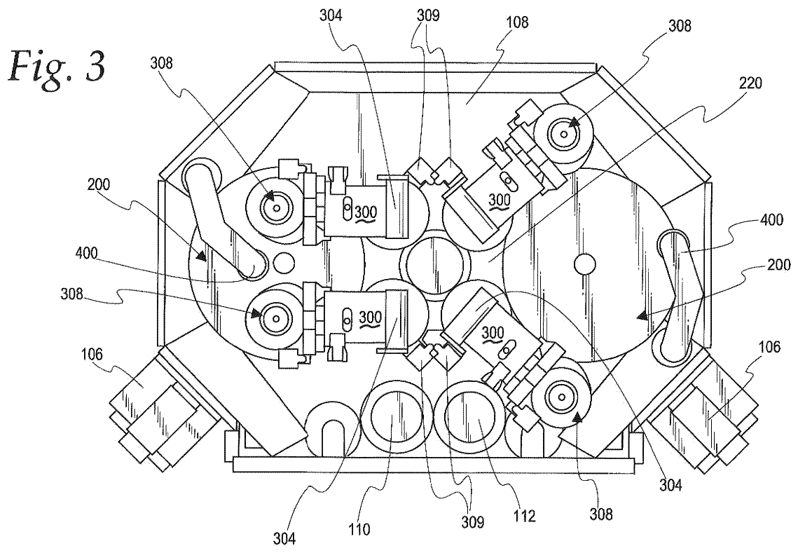

Seen in FIG. 3, drain pan 108 collects operating fluids, slurry and rinse water, used during the polishing process and channels them to drain.

Frame 102 includes wafer loading/unloading stations 110 and 112 along one longitudinal edge of frame 102 mid-way between mounts 104. In an automated system, wafers to be processed are delivered to these locations by a wafer handling robot or transport mechanism, and accessed by the machine's wafer carriers for processing, as will be explained.

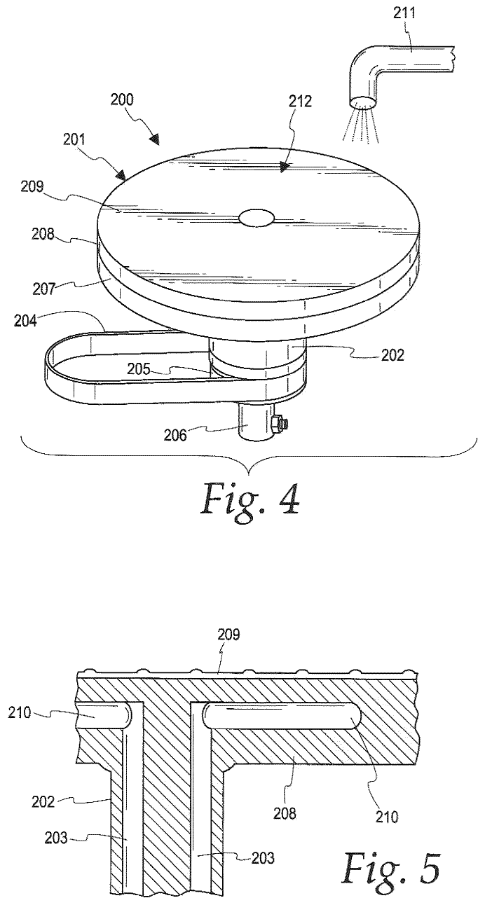

The machine 100 includes two spaced apart polishing stations having polishing assemblies 200 generally supported on frame 102 at each mount 104. Each polishing assembly 200, shown in FIGS. 4 and 5, includes a circular generally planar platen 201 having a vertical shaft 202. Shafts 202 each include hollow fluid passages 203, seen in FIG. 5 that connect through rotary union 206 (See FIG. 4) to a platen cooling circuit as discussed further below.

The drive motors 107 on frame 102 rotate the platens 201 through belts 204 and pulleys 205 at a predetermined rotational speed, nominally 160 RPM or lower.

Each circular platen 201 is comprised of a rigid support plate 207, an aluminum backing plate 208, and a vertically upward facing polishing surface 212 defined by polishing pad 209 adhered to the platen 201. Aluminum backing plates 208 include multiple passages 210 for circulating coolant (water) from a heat exchanger (sometimes referred to as a “closed loop chiller”) of the platen cooling circuit to control the temperature of polishing pad 209. The coolant passages 210 can be formed into the aluminum backing plate 208 by drilling or machining or may be cast into the aluminum backing plates 208. For example, an aluminum alloy backing plate with a thickness of 1 ¼ to 2 inches is easy to machine and has sufficient stiffness and flatness to be suitable for a chemical mechanical polishing operation. To protect the aluminum from chemical degradation, chemically resistant coatings can be applied for use with certain slurries. The coolant passages 210 are arranged to extend horizontally and radially outward to the circumferential perimeter of the aluminum backing plate 208 and may be parallel to and spaced below the upper surface of the aluminum backing plate 208 on which the polishing pad 209 is supported. The radial coolant passages 210 can intersect and fluidly communicate with the hollow fluid passages 203 that are vertically oriented within the upright shaft 202.

Each polishing pad 209 is a polymeric material configured to provide asperities upon a generally planar polishing surface. Such asperities contribute to the polishing effectiveness of pad 209.

Seen in FIG. 3, indexing table 220 disposed centrally between polishing assemblies 200 is rotatably supported on central pedestal 103 of frame 102. Indexing table 220 is configured for 270 degrees of rotation. It is also configured to firmly lock at 90 degree intervals at each index position during polishing.

Referring now to FIG. 3 two polishing arms 300 extend over each platen 201 of each polishing assembly 200. Each arm 300 is pivotally supported at a proximal end 304 upon indexing table 220. A distal end includes polishing head assembly 308. Polishing arms 300 are powered by servo motors 309 and arranged to pivot relative to indexing table 220 to perform loading, unloading and wafer oscillating functions.

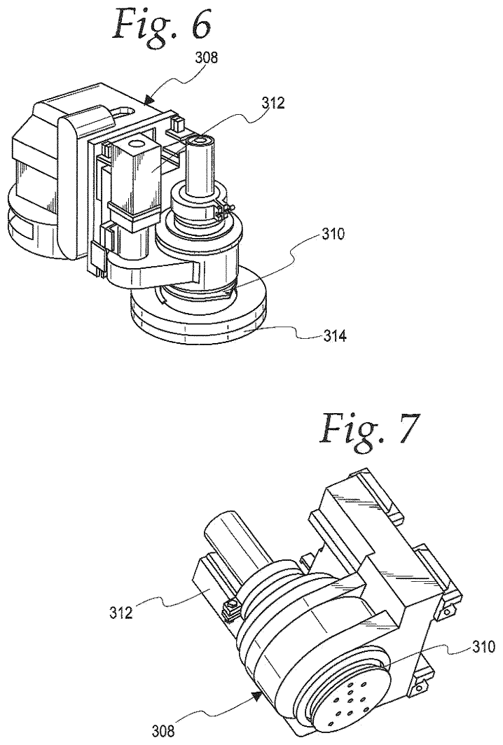

Referring to FIGS. 6 and 7, each polishing head assembly 308 rotatably supports a wafer carrier plate 310 driven by motor 312 upon which is mounted a wafer carrier 314. Each carrier 314 secures a single wafer to be polished in the proper orientation to the upward surface of a polishing pad 209. The precise configuration of the mechanism of the wafer carrier 314 may vary, depending on the shape and composition of the wafers and the polishing objectives to be achieved.

In operation, platen 201 is rotated at a predetermined speed. Similarly, a planar surface of a wafer being processed, carried upon a wafer carrier 314, is rotated at a predetermined speed, for example 175 RPM. The wafer is pressed into contact with the polishing surface 212 of polishing pad 209 at a controlled pressure, for example 9 PSI (pounds per square inch). At the same time, the polishing head assembly 308 on arm 300 is oscillated in an arcuate path across the polishing surface 212 of pad 209. The polishing action at the wafer/polishing surface interface is, thus, distributed across the polishing pad 209 in an enlarged annular pattern sometimes referred to as the “wafer track.”

To dispense a liquid slurry that has been chilled, adjacent each polishing head assembly 308, the wafer polishing apparatus may include a slurry delivery circuit including slurry delivery tubes 211 located generally over the upper polishing surface 212 of the polishing pad 209 (as shown schematically in FIG. 4). The flow quantity of the chilled liquid slurry may be adjusted, for example, by metering pumps and can be set to maintain a pad surface temperature measured at the upper polishing surface 212 at approximately 55° C.

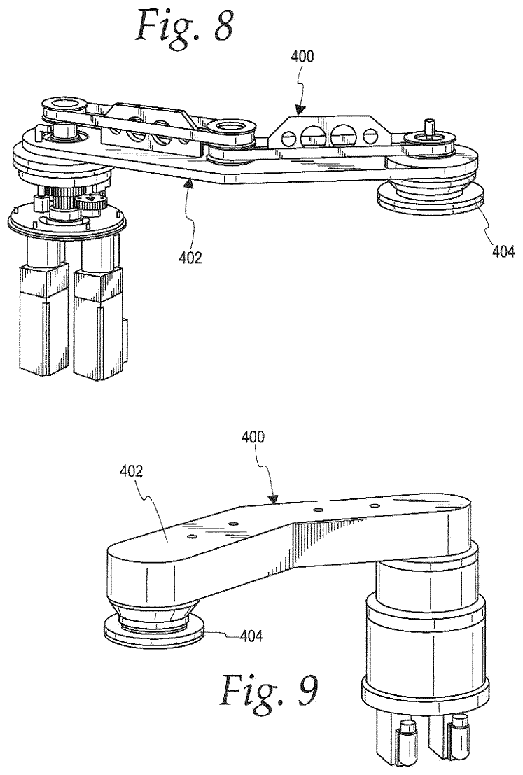

Machine 100 also includes pad conditioning assemblies 400 mounted on frame 102 adjacent each polishing assembly 200. Shown in FIGS. 8 and 9 each conditioning assembly 400 includes arm 402 carrying a rotatable pad conditioning disk 404 at its free end. The opposite end of arm 402 is mounted in operative association with drive motors 406 to accommodate pivotal movement of arm 402 and, through belts and pulleys, rotation of pad conditioning disk 404. Each pad conditioning disk is arranged to oscillate over a polishing pad 209 with pad conditioning disk 404 in rotational contact with upper surface of polishing pad 209 to recondition the surface throughout the wafer track portion of polishing pads 209.

Polishing slurry is one of the most critical polishing consumables in the CMP process. The major benefit of this adaptation is that the chilled slurry is dispensed directly onto the surface of polishing pad 209 at the wafer/pad surface interface. Chilled slurry is dispensed in controlled quantities through the open ends of delivery, or drip tubes 211 (for example, at 25 to 400 ml/min) to the interface between the exposed surface of a wafer residing in a rotating polishing carrier 314 and polishing pad 209 on a rotating platen 201. This provides a coolant directly to the pad surface where most of the heat is being generated. The delivery tubes 211 are components of the slurry delivery circuit including supply tank, pumps 106, and slurry temperature monitoring and control devices. A delivery tube 211 can be provided for each platen of each polishing assembly 200 included with the wafer polishing machine 100. The delivery tubes 211 can fluidly communicate with the same pumps and supply tanks.

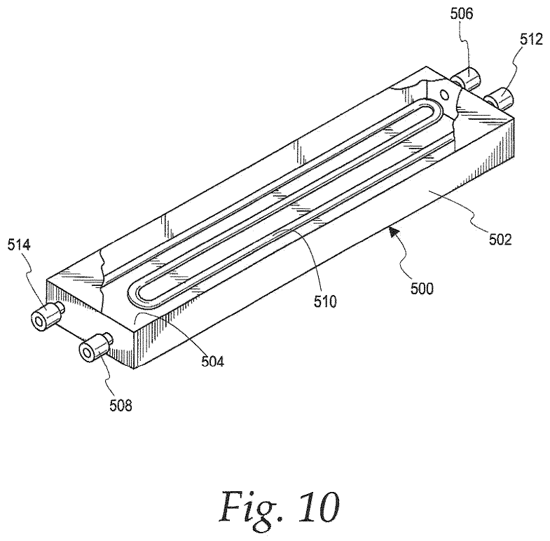

In accordance with the disclosure, the slurry delivery circuit includes a heat exchanger or closed loop chiller 500. Schematically represented in FIG. 10, heat exchanger 500 is provided to maintain the desired temperature of the slurry delivered to the polishing process. It includes housing 502 defining an internal volume 504. Heat exchange fluid, usually water, at a controlled temperature, flows through the housing volume from an inlet coupling 506 to an outlet coupling 508. The heat exchanger fluid temperature is variable and controlled in accordance with overall process requirements.

Housing 500 also includes a slurry flow path in the form of an internal array of heat exchange tubes 510 extending between a slurry inlet coupling 512 and a slurry discharge coupling 514.

Tubes 510 within housing 502 provide a surface area along which heat exchange occurs between the flowing heat exchange fluid and the flowing slurry. Liquid slurry exiting slurry discharge coupling 514 is carried by the delivery tubes 211 and dispensed into the polishing process. The closed loop chiller 400 can deliver slurry to each of the delivery tubes 211 associated with each of the polishing assemblies on the multi-platen polishing machine.

Although, not specifically discussed, in the specification or shown in the drawings, the exemplary wafer polishing machine 100 includes all components necessary to perform the wafer polishing process upon multiple wafers simultaneously. Toward that end, machine 100 includes all power and communication cables, fluid conduits, pressurized air and vacuum supplies, pumps, tubes, and water and slurry containers and lines necessary to its function, as well as servo motors, shafts, gears, bearings, and drive mechanisms. As is common in the industry, operation is directed through appropriate electronic monitoring and control systems, including, display monitors, input keyboards, central processing unit (CPU), programmable logic controller (PLC) and human machine interface (HMI). These components are considered a part of the disclosure and fully understood by persons of ordinary skill in the art.

Application of the principles of the disclosure to attain optimal performance of CMP polishing of SIC wafers is described above with reference to the disclosed exemplary embodiment. The underlying principles, as summarized below, are however, beneficial to any wafer polishing process sufficiently aggressive to render problematic the polishing pad surface temperature.

The first component of the combined cooling approach of the disclosure is to configure the polishing machine 100 with a larger diameter polishing pad than is typically used for 150 mm or 200 mm wafers, which is in the range of 18 inches to 24 inches. The disclosed embodiment here, for improved cooling incorporates a platen 201 having a pad diameter of polishing pad 209 in the range of 28 to 36 inches. The energy from the polishing process is imparted into the surface area of the wafer track on pad 209, and, assuming the pad surface temperature is a function of energy per unit area per unit time, the average surface temperature of the pad 209 can be lowered by increasing the area of the wafer track. As an example, polishing a 150 mm wafer, with a polishing pad diameter of the current disclosure of 30 inches rather than a conventional pad diameter of 20 inches, increases the wafer track area by approximately a 91%. This result assumes a sweep or oscillation of the wafer of one inch, and the outer radius of the wafer track set one inch from the outer perimeter edge of the pad 209.

In an example, based on a platen diameter of 30 inches and a wafer diameter of approximately 6 inches, the annular wafer track over the upper polishing surface 412 of the polishing pad 209 can have an outer diameter of 29 inches and an inner dimeter of 15 inches. The outer and inner diameter are based on an assumption that the annular wafer track is offset one inch inward from the platen diameter or circumference, and the wafer carrier 314 oscillates with respect to the rotating polishing platen 209 in one-inch sweeps. The surface area of the annular wafer track is therefore approximately 425 square inches.

The second adaptation involves actively cooling the platen 201 underneath the surface of polishing pad 209. The platen 201, as illustrated in the disclosed embodiment supports the polishing pad 209 during the polishing process. Flow of cooling water through passages 210 to the interior of the platen 201 under pad 209 may be implemented using a heat exchanger similar to FIG. 10. The heat exchanger may be located separately apart from the polishing assemblies 200 and can be supported elsewhere on the structural support frame 102. Fresh low temperature coolant or water can be directed from the heat exchanger through the hollow fluid passages 203 in the upright shaft 202 to the coolant passages 210 extending horizontally or radially in the aluminum platen 201. The cooling water or coolant absorbs thermal energy in the form of heat by conduction through the aluminum material of the platen and is transferred away from the polishing assembly 200 by the radial coolant passages 210 fluidly communicating with the hollow fluid passages 203. The platen cooling circuit maintains a stable controlled temperature at the core of the platen 201 is a key component of the envisioned combination of features for optimal pad surface cooling. The platen cooling circuit may be set to maintain the core temperature of platen 201 in the range of 5 to 15 degrees C.

The third adaptation for optimal pad surface cooling relates to the material selection for the platen. Platens 201 can be made from various materials, including steel, stainless steel, or ceramics that maintain structural integrity under the expected load. While stainless steel is a conventional material for a platen due to low chemical reactivity, easy availability, ease of manufacturing, and reasonably low cost, the thermal properties of stainless steel are vastly inferior to most structural grades of aluminum. Due to differences in thermal conductivity, heat flow through an aluminum component is generally about four times higher than heat flow through the same component made from stainless steel. Aluminum also has similar attributes of easy availability, ease of manufacturing, and reasonably low cost. For maximum dissipation of heat through the bottom of the polishing pad, the preferred platen 201 should, as disclosed herein, be made of aluminum or an aluminum alloy.

The fourth adaptation for optimal cooling of platen polishing pad 201 is to provide a means to cool or chill the incoming slurry. Since the polymeric material of pad 209 itself acts as a partially insulating layer between the top surface of the pad and the platen 201 which serves as a heat sink, dissipation of heat is compromised. For aggressive polishing processes as contemplated here, this can still be a limiting factor for controlling the surface temperature of polishing pad 209. Thus, chilling the slurry just prior to dispensing onto the surface of pad 209 provides an additional pathway for absorbing frictional heat generated during polishing. In accordance with the disclosure, with reference to FIG. 10, chilling can be accomplished with the flow-through heat exchanger 500 having a length of slurry tubing 510 directed through a cavity or volume 504 supplied with flowing chilled water or other coolant.

It is also contemplated that the heat exchanger that provides cooling water to the platens 201 can be plumbed to also flow chilled coolant through the slurry heat exchanger 500. A key attribute is that the slurry path should be sealed against cross-mixing, and the total slurry volume should be relatively small to avoid settling within the cooler tubes. Also, the heat exchange coolant liquid should be refreshed at a sufficient rate to maintain the desired temperature range, for example, below 55° C.

Use of the disclosed cooling approach enables more aggressive process conditions with higher interface pressure and relative surface speeds while still maintaining the polishing pad temperature below the critical temperature, this increases removal rates and increases wafer throughput.

The terms “a” and “an” and “the” and “at least one” and similar references in the context of describing the disclosed embodiments are in the context of attached claims are to be construed to cover both the singular and the plural, unless otherwise indicated herein or clearly contradicted by context. The use of the term “at least one” followed by a list of one or more items (for example, “at least one of A and B”) is to be construed to mean one item selected from the listed items (A or B) or any combination of two or more of the listed items (A and B), unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of examples, or exemplary language (e.g., “such as”) provided herein, is intended merely to better illuminate the invention, and does not pose a limitation on the scope of the invention unless otherwise claimed. No language in the specification should be construed as indicating any non-claimed element as essential to the practice of the invention.

Preferred embodiments are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

1. A wafer polishing apparatus for the aggressive polishing of a semiconductor wafer comprising:
a rotatable circular platen comprised of aluminum having a polishing pad adhered thereto defining a polishing surface, and having a diameter of approximately 28 to 36 inches,
said platen including one or more fluid passages therein,
at least one carrier for carrying a wafer in polishing contact with said polishing surface along a wafer/polishing surface interface,
a closed-loop platen cooling circuit including a chiller for directing coolant to said one or more fluid passages; and
a slurry delivery circuit having at least one slurry delivery tube for delivering chilled liquid slurry to the polishing surface adjacent said wafer/polishing surface interface.

2. The wafer polishing apparatus of claim 1, wherein the at least one slurry delivery tube connects to a heat exchanger for exchange of thermal energy between the liquid slurry and a heat exchanger fluid.

3. The wafer polishing apparatus of claim 2, wherein the wafer carrier is configured to oscillate the wafers with respect to the polishing surface of the rotatable platen, thereby producing an annular wafer track over the polishing pad.

4. The wafer polishing apparatus of claim 3, wherein the wafer comprises silicon carbide (SiC) and has a diameter of at least 150 mm.

5. The wafer polishing apparatus of claim 4, wherein the temperature of the polishing surface of the polishing pad is maintained at or below approximately 55° C.

6. The wafer polishing apparatus of claim 4, wherein the chiller of the platen cooling circuit also serves as the source for the chilled water or coolant in the heat exchanger of the slurry delivery circuit.

7. The wafer polishing apparatus of claim 4 wherein the wafer track has a surface area of approximately 425 square inches.

8. The wafer polishing apparatus of claim 5, further comprising multiple wafer carriers for placing wafers in polishing contact with the polishing surface of the polishing pad and multiple delivery tubes to deliver chilled liquid slurry to the polishing surface adjacent each wafer/polishing surface interface.

9. The wafer polishing apparatus of claim 1, further comprising multiple platens, with multiple wafer carriers and multiple chilled slurry delivery tubes associated with each platen.

10. A method of polishing semiconductor wafers comprising:
providing a rotatable circular aluminum platen having a diameter of from 28 to 36 inches and a polishing pad adhered thereto defining a polishing surface, said platen further including one or more fluid passages therein,
providing at least one carrier for carrying a wafer in polishing contact with said polishing surface along a wafer/polishing surface interface,
providing a platen cooling circuit including a chiller for directing coolant to the one of more fluid passages in the platen,
providing a slurry delivery circuit including a heat exchanger and at least one slurry delivery tube for delivering chilled liquid slurry to the polishing surface adjacent said wafer/polishing surface interface,
rotating the at least one wafer in polishing contact with the polishing surface of the polishing pad adhered to the rotating circular platen along a wafer/polishing surface interface,
circulating a coolant through the platen cooling circuit to the one or more fluid passages in the platen,
cooling a liquid slurry within the slurry delivery circuit and delivering the cooled slurry to the polishing pad adjacent the at least one wafer/polishing pad interface.

11. The method of claim 10, further comprising oscillating the at least one wafer carrier with respect to the polishing surface of the rotating platen to produce an annular wafer track on the polishing surface of said polishing pad.

12. The method of claim 11, further including maintaining the pad surface temperature measured at the upper polishing surface of the polishing pad at or below approximately 55° C.

13. The method as claimed in claim 11, wherein multiple wafer carriers are provided, each rotating a wafer in polishing contact with the polishing surface of the polishing pad adhered to a rotating circular platen along a wafer/polishing surface interface, and multiple delivery tubes are provided delivering chilled liquid slurry to the polishing surface adjacent each wafer/polishing surface interface.

14. The method of claim 13, wherein said wafers are comprised of silicon carbide (SIC) and have a diameter of at least 150 mm.

15. The method of claim 13, wherein the chiller of the platen cooling circuit also serves as the source for the chilled water or coolant in the heat exchanger of the slurry delivery circuit.

16. The method of claim 13 further comprising providing multiple platens with multiple wafer carriers associated with each platen, the steps comprising, polishing multiple wafers at the same time.
